(19) United States
(12) Patent Application Publication
(10) Pub. No.: US 2013/0285093 A1
(43) Pub. Date: Oct. 31, 2013

(54) LIGHT EMITTING DIODE PACKAGE STRUCTURE HAVING A SUBSTRATE INCLUDING CERAMIC FIBERS

(71) Applicant: ADVANCED OPTOELECTRONIC TECHNOLOGY, INC., (US)

(72) Inventor: HSING-FEN LO, Hsinchu (TW)

(73) Assignee: ADVANCED OPTOELECTRONIC TECHNOLOGY, INC., Hsinchu Hsien (TW)

(21) Appl. No.: 13/728,935

(22) Filed: Dec. 27, 2012

(30) Foreign Application Priority Data
Apr. 27, 2012 (CN) 201210126812.1

(51) Int. Cl. H01L 33/48

(52) U.S. Cl. CPC H01L 33/483
USPC 257/98

(57) ABSTRACT

An LED package structure includes a substrate and an LED chip formed on the substrate. The substrate has a first electrode and a second electrode formed on an upper surface thereof. The LED chip is formed on the first electrode of the substrate and electrically connected with the first electrode and the second electrode respectively. The substrate is made of a composite including a base material and ceramic fibers mixed in the base material.

### BACKGROUND

1. Technical Field

The disclosure generally relates to a light emitting diode (LED) package structure, and particularly to an LED package having a substrate which is made of a composite of a base material and ceramic fibers to improve mechanical connection between the substrate and electrodes attached to the substrate.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

An LED package structure includes a substrate and an LED chip formed on the substrate. Electrodes are formed on the substrate to electrically connect with the LED chip. Generally, the substrate is made of a base material and glass fibers mixed in the base material. Because the arranged direction of the glass fibers is difficult to control, the connection between the substrate and the electrodes is weak. The glass fibers are inclined to float to a surface of the substrate to affect the connection between the electrodes and the substrate. The floated glass fibers also affect the smoothness of the surface of the substrate. In addition, the substrate with the glass fibers has a large degree of shrinkage after curing of the substrate, which affects an intimate connection between the substrate and the electrodes.

What is needed, therefore, is an LED package structure to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing an LED package structure in accordance with an embodiment of the present disclosure.

FIG. 2 is a microscopic view showing a portion of a substrate of the LED package structure in FIG. 1.

FIG. 3 includes two diagrams respectively showing a roughness of a substrate with ceramic fibers and a roughness of a substrate with glass fibers.

### DETAILED DESCRIPTION

An embodiment of an LED package structure will now be described in detail below and with reference to the drawings.

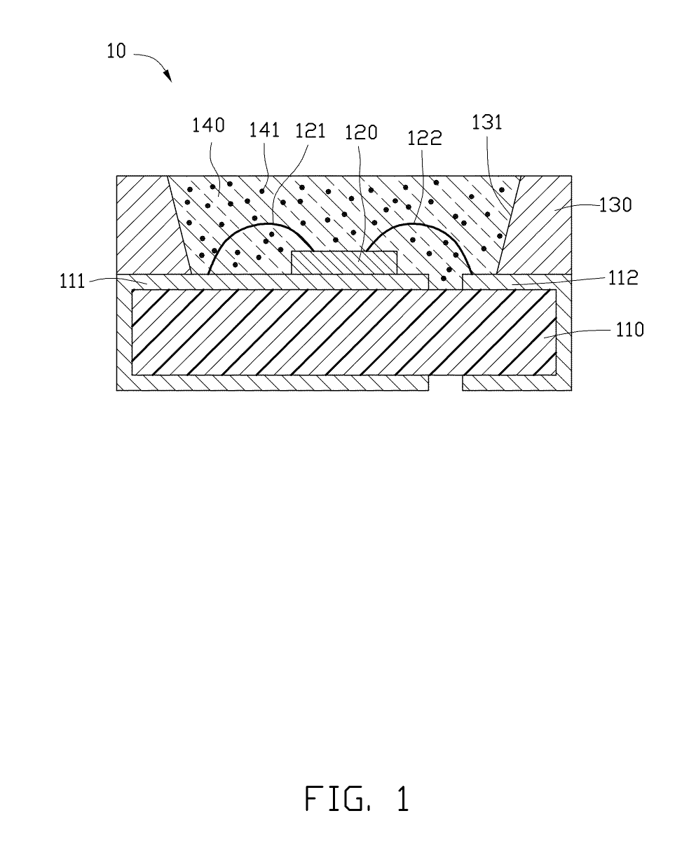

Referring to FIG. 1, an LED package structure 10 is provided. The LED package structure 10 includes a substrate 110, an LED chip 120, a reflector 130 and an encapsulation 140.

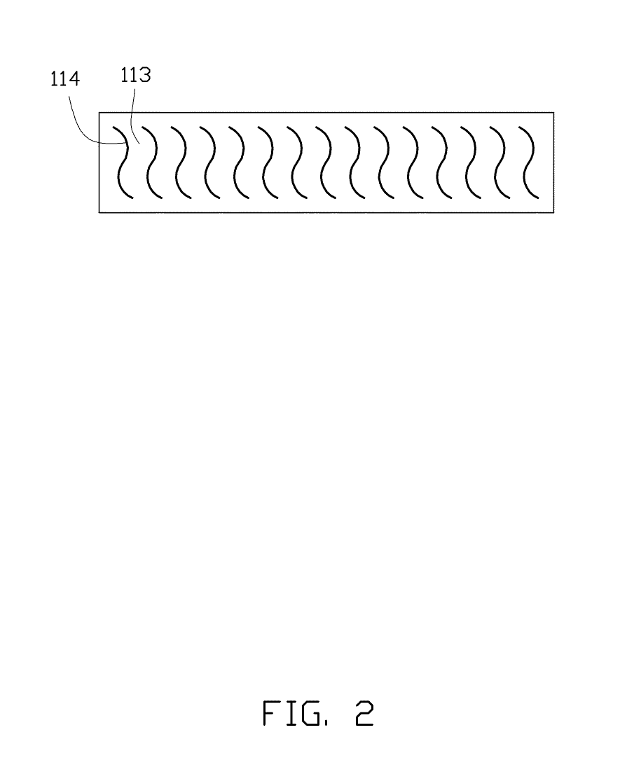

The substrate 110 has a first electrode 111 and a second electrode 112 formed on an upper surface thereof. The first electrode 111 and the second electrode 112 are electrically insulated with each other. In this embodiment, the first electrode 111 extends downwardly from the upper surface of the substrate 110 to a bottom surface of the substrate 110. The second electrode 112 also extends downwardly from the upper surface of the substrate 110 to the bottom surface of the substrate 110. The first electrode 111 and the second electrode 112 are formed at two opposite ends of the substrate 110. Preferably, portions of the first electrode 111 and the second electrode 112 on the bottom surface of the substrate 110 are exposed to outer environment thereby forming a surface mounting structure to electrically connect with external power. The first electrode 111 and the second electrode 112 are made of a material selected from a group consisting of Au, Ag, Al, Ni, Cu and alloys thereof. Referring also to FIG. 2, the substrate 110 is made of a base material 113 and ceramic fibers 114 mixed in the base material 113. The base material 113 is selected from a material selected from a group consisting of polyphthalmide (PPA), polycarbonate (PC), polymethylmethacrylate (PMMA), epoxy, silicone and mixtures thereof. The ceramic fibers 114 are made of K₂Ti₆O₁₃. Each ceramic fiber 114 has a length of 10-80 μm and a diameter of 0.2-1.5 μm.

The LED chip 120 is formed on the first electrode 111. The LED chip 120 is electrically connected with the first electrode 111 and the second electrode 112 with a first wire 121 and a second wire 122 respectively. The LED chip 120 is made of a material selected from a group consisting of GaN, AlGaN, InGaN and AlInGaN.

The reflector 130 is formed on the upper surface of the substrate 110 and surrounds the LED chip 120. The reflector 130 and the substrate 110 together form a reflective chamber 131. A size of the reflective chamber 131 gradually increases in a direction away from the substrate 110 toward a top of the reflector 130. Preferably, the reflector 130 and the substrate 110 can be integrally formed with the same material and as a monolithic piece. That is, the reflector 130 can also be made of the base material 113 and the ceramic fibers 114 mixed in the base material 113.

The encapsulation 140 is filled in the reflective chamber 131 formed by the reflector and the substrate 110, thereby covering the LED chip 120. Preferably, the encapsulation 140 can be doped with phosphor particles 141. The phosphor particles 141 absorb light from the LED chip 120 and emit a light with a wavelength different from that of the light from the LED chip 120. The phosphor particles 141 are made of a material selected from a group consisting of sulfides, silicates, nitrides, nitrogen oxides, hydroxid, garnets and mixtures thereof.

In the LED package structure 10 described above, the substrate 110 includes the base material 113 and the ceramic fibers 114 mixed in the base material 113. Because the ceramic fibers 114 have a good connection with a metal material, the connection between the substrate 110 and the first electrode 111 and the second electrode 112 is strengthened. In addition, with the ceramic fibers 114 to replace the glass fibers, the LED package structure 10 will be resistant to high temperature. Therefore, the substrate 110 or the reflector 130 is not easy to be aging in a high temperature. Furthermore, with the ceramic fibers 114, the LED package structure 10 will have a smooth surface. Finally, since the degree of shrinkage of the composite of the base material 113 and the ceramic fibers 114 after curing is relatively low, in comparison with the composite of the base material 113 and plastic fibers, the tightness of connection between the electrodes 111, 112 and the substrate 110 can be further improved.

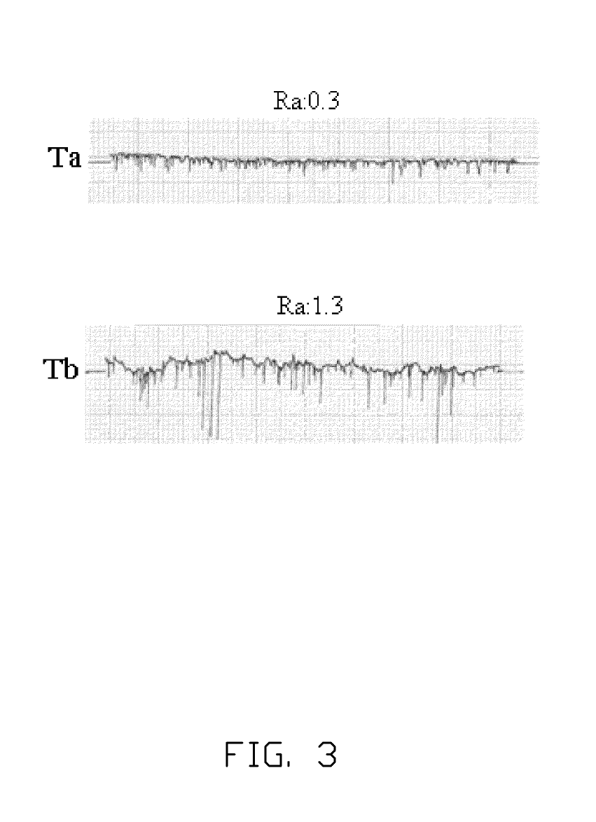

Referring to FIG. 3, Ta represents a curve of roughness of the surface of the substrate 110 with the ceramic fibers 114, and Tb represents a curve of roughness of a substrate with glass fibers. As shown in FIG. 3, the roughness Ra of the substrate 110 with the ceramic fibers 114 is 0.3, and the roughness Ra of the substrate with the glass fibers is 1.3, wherein Ra represents an arithmetic mean of values of the longitudinal coordinates in a predetermined range. Therefore, the roughness of the substrate 110 with the ceramic fibers 114 is less than that of the substrate with the glass fibers. That is, the substrate 110 with the ceramic fibers 114 will be more smooth than the substrate with the glass fibers.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED package structure, comprising:
a substrate, having a first electrode and a second electrode formed on an upper surface thereof; and
an LED chip, formed on the first electrode of the substrate, the LED chip being electrically connected with the first electrode and the second electrode respectively;
wherein the substrate is made of a base material with ceramic fibers mixed in the base material.

2. The LED package structure of claim 1, wherein the ceramic fibers are made of K₂Ti₆O₁₃.

3. The LED package structure of claim 1, wherein the base material is made of a material selected from a group consisting of polyphthalmide, polycarbonate, polymethylmethacrylate, epoxy, silicone and mixtures thereof.

4. The LED package structure of claim 1, wherein a reflector is formed on the upper surface of the substrate, the reflector surrounds the LED chip, and the reflector and the substrate together form a reflective chamber.

5. The LED package structure of claim 4, wherein a size of the reflector chamber gradually increases in a direction away from the substrate toward a top of the reflector.

6. The LED package structure of claim 5, wherein the reflector and the substrate are integrally formed with the same material and as a monolithic piece.

7. The LED package structure of claim 6, wherein the reflector is made of a base material with ceramic fibers mixed in the base material, and the base material is made of a material selected from a group consisting of polyphthalmide, polycarbonate, polymethylmethacrylate, epoxy, silicone and mixtures thereof.

8. The LED package structure of claim 7, wherein the ceramic fibers are made of K₂Ti₆O₁₃.

9. The LED package structure of claim 4, wherein the reflective chamber is filled with an encapsulation, and the encapsulation covers the LED chip.

10. The LED package structure of claim 9, wherein the encapsulation is doped with phosphor particles.

11. The LED package structure of claim 10, wherein the phosphor particles are made of a material selected from a group consisting of sulfides, silicates, nitrides, nitrogen oxides, hydroxid, garnets and mixtures thereof.

12. The LED package structure of claim 1, wherein the first electrode and the second electrode are formed at two opposite ends of the substrate, the first electrode extends from the upper surface to a bottom surface of the substrate, and the second electrode also extends from the upper surface to the bottom surface of the substrate.

13. The LED package structure of claim 1, wherein a roughness of the substrate, Ra, is 0.3.

14. The LED package structure of claim 1, wherein the first electrode and the second electrode are made of a material selected from a group consisting of Au, Ag, Al, Ni, Cu and alloys thereof.

15. The LED package structure of claim 2, wherein each of the ceramic fibers has a length of 10-80 μm and a diameter of 0.2-1.5 μm.
